(19) United States
(12) Patent Application Publication
(10) Pub. No.: US 2024/0247398 A1
(43) Pub. Date: Jul. 25, 2024

(54) INGOT PULLER APPARATUS AND METHODS FOR GROWING A SINGLE CRYSTAL SILICON INGOT WITH REDUCED LOWER CHAMBER DEPOSITS

(71) Applicant: GlobalWafers Co., Ltd., Hsinchu (TW)

(72) Inventors: Carissima Marie Hudson, St. Charles, MO (US); JaeWoo Ryu, Chesterfield, MO (US); William Lynn Luter, St. Charles, MO (US); Matteo Pannocchia, Lana (IT)

(21) Appl. No.: 18/410,347

(22) Filed: Jan. 11, 2024

Related U.S. Application Data
(60) Provisional application No. 63/480,663, filed on Jan. 19, 2023.

(51) Int. Cl. C30B 15/00; C30B 29/06

(52) U.S. Cl. CPC C30B 15/00; C30B 29/06

(57) ABSTRACT

Ingot puller apparatus and methods for growing a single crystal silicon ingots with reduced lower chamber deposits are disclosed.

### CROSS-REFERENCE TO RELATED APPLICATIONS

This application claims the benefit of U.S. Provisional Patent Application Number 63/480,663, filed Jan. 19, 2023, which is incorporated herein by reference in its entirety.

### TECHNICAL FIELD

The field of the disclosure relates to ingot puller apparatus and methods for growing a single crystal silicon ingots with reduced lower chamber deposits.

### BACKGROUND

Single crystal silicon ingots may be grown by the so-called Czochralski process in which a silicon seed crystal is contacted with a melt of silicon. The silicon seed crystal is withdrawn from the melt causing a single crystal silicon ingot suspended by the seed crystal to form.

In ingot pullers that grow multiple crystals per batch, the upper pull chamber is separated from the lower chamber by an isolation valve. Conventionally, the upper chamber is separated from the lower chamber when (1) seed material is replaced, (2) the seed cable is replaced, and (3) the grown ingot is removed to isolate the molten silicon in the lower growth chamber.

Separation and reconnection of the two chambers may be achieved with appropriate control of pressure in both chambers, maintained by proper vacuum pump and process gas supply (e.g., argon). When the isolation valve is open, process gas from the main inlet at the top of the ingot puller flows downward with strong laminar flow because gas direction is from top to bottom. When the isolation valve is closed, another process gas inlet located at the side of grower chamber and below the isolation valve is used to introduce process gas which results in process gas that flows horizontally or at some other relatively large angle with respect to the pull axis of the ingot puller apparatus. This turbulent flow stream in the upper portion of the lower chamber of the puller can impact particle deposition on the hot zone components.

Silicon oxides evaporate from the melt free surface during ingot processing. The evaporation rate is affected by the process recipe that is used during crystal growth to achieve a desired oxygen content in the crystal. Oxide evaporation affects the success of single crystal growth because evaporated oxide particles deposit on the cold walls in the puller and the deposits subsequently drop to the melt surface during crystal growth. Volatile doping elements can also evaporate from the melt surface and deposit on the cold wall surfaces inside of the ingot puller. Evaporating volatile dopants enhance the evaporation of silicon oxide gases from the melt surface and increase deposits. The deposits that form in the ingot puller apparatus (e.g., cooling jacket) may dislodge during ingot growth which may result in loss of zero dislocation growth of the single crystal silicon ingot or may cause defects to form in the ingot (e.g., slip or twin lamella).

A need exists for ingot puller apparatus and methods for growing a single crystal silicon ingot that are able to reduce deposits that form during ingot processing.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to an ingot puller apparatus for producing a single crystal silicon ingot. The ingot puller apparatus includes a crucible assembly for holding a silicon melt. An ingot puller housing defines a growth chamber for pulling a silicon ingot from the silicon melt. The crucible assembly is disposed within the growth chamber. The ingot puller housing includes a lower segment and an upper segment. The lower segment defines a lower segment chamber. The crucible assembly is disposed in the lower segment chamber. The upper segment is disposed above the lower segment and defines an upper segment chamber. The apparatus includes an isolation valve that is moveable between an open position in which the lower segment chamber is in fluid communication with the upper segment chamber and a closed position in which the lower segment chamber is sealed from the upper segment chamber. The apparatus includes a process gas feed assembly having an inlet that extends through the ingot puller housing for introducing a process gas into the growth chamber. A nozzle is in fluid communication with the inlet for directing process gas into the lower segment chamber.

Another aspect of the present disclosure is directed to an ingot puller apparatus for producing a single crystal silicon ingot. The apparatus includes a crucible assembly for holding a silicon melt. An ingot puller housing defines a growth chamber for pulling a single crystal silicon ingot from the silicon melt along a pull axis. The crucible assembly is disposed within the growth chamber. The ingot puller housing includes a lower segment and an upper segment. The lower segment defines a lower segment chamber. The crucible assembly is disposed in the lower segment chamber. The upper segment is disposed above the lower segment and defines an upper segment chamber. The apparatus includes an isolation valve that is moveable between an open position in which the lower segment chamber is in fluid communication with the upper segment chamber and a closed position in which the lower segment chamber is sealed from the upper segment chamber. The apparatus includes a process gas feed assembly. The process gas feed assembly includes an inlet that extends through the ingot puller housing for introducing a process gas into the growth chamber. A shower plate is disposed below the isolation valve. The shower plate is in fluid communication with the inlet. The shower plate includes a plurality of outlets for discharging process gas into the lower segment chamber.

Yet another aspect of the present disclosure is directed to a method for forming a single crystal silicon ingot in an ingot puller apparatus. The ingot puller apparatus includes a crucible assembly for holding a silicon melt and an ingot puller housing that defines a growth chamber for pulling a single crystal silicon ingot from the silicon melt. The crucible assembly is disposed within the growth chamber. The ingot puller housing includes a lower segment that defines a lower segment chamber and an upper segment disposed above the lower segment that defines an upper segment chamber. The crucible assembly is disposed in the lower segment chamber. An isolation valve is moveable between an open position in which the lower segment chamber is in fluid communication with the upper segment chamber and a closed position in which the lower segment chamber is sealed from the upper segment chamber. A charge of solid-state silicon is added to the crucible assembly. The crucible assembly comprising the charge of silicon is heated to cause a silicon melt to form in the crucible assembly. A silicon seed crystal is contacted with the silicon melt. The silicon seed crystal is withdrawn along a pull axis to grow a single crystal silicon ingot. The single crystal silicon ingot is separated from the melt. The single crystal silicon ingot is cooled while the ingot is fully within the upper segment chamber after separating the single crystal silicon ingot from the melt. The isolation valve is in the open position while the single crystal silicon ingot is cooled. Process gas is directed through the upper segment chamber and into the lower segment chamber while cooling the single crystal silicon ingot in the upper segment chamber. The single crystal silicon ingot is withdrawn from the upper segment chamber. The isolation valve is in the closed position while withdrawing the single crystal silicon ingot.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section of an ingot puller apparatus during ingot growth;

FIG. 2 is a schematic of an ingot puller apparatus having an upper segment and lower segment;

FIG. 3 is a schematic of an ingot puller apparatus showing an isolation valve and process gas feed assembly;

FIG. 4 is a schematic of an ingot puller apparatus in which the process gas feed assembly includes a nozzle;

FIG. 5 is a schematic of the nozzle;

FIG. 6 is a schematic of an ingot puller apparatus in which the process gas feed assembly includes a shower plate;

FIG. 7 is a schematic of the ingot puller apparatus of FIG. 6 showing the process gas flow;

FIG. 8 is a schematic of the ingot puller apparatus of FIG. 4 showing the process gas flow; and

FIG. 9 is a graph of the normalized ratio of Zero Dislocation (ZD) growth success between conventional methods (“Before”) and methods in which the isolation valve is opened during cooling (“After”) as described in Example 1.

Corresponding reference characters indicate corresponding parts throughout the drawings.

### DETAILED DESCRIPTION

Provisions of the present disclosure relate to ingot puller apparatus that improve the flow of process gas in the lower segment of the ingot puller apparatus while the isolation valve is closed and to methods for preparing a single crystal silicon ingot with improved process gas flow.

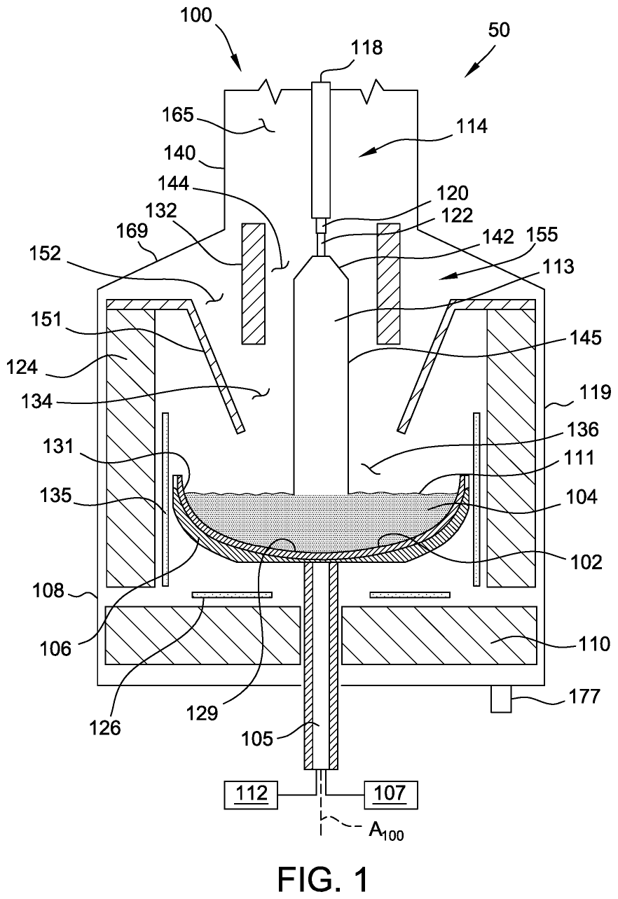

An example ingot puller apparatus (or more simply “ingot puller”) is indicated generally as “100” in FIG. 1. The ingot puller apparatus 100 includes a crucible assembly 102 for holding a melt 104 of semiconductor or solar-grade material silicon. The crucible assembly 102 is supported by a susceptor 106.

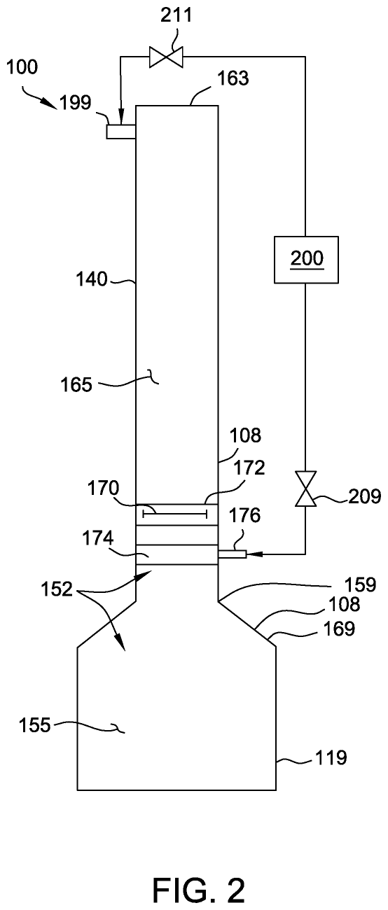

The ingot puller apparatus 100 includes an ingot puller housing 108 that defines a growth chamber 152 for pulling a single crystal silicon ingot 113 from the silicon melt 104 along a pull axis A₁₀₀. Referring now to FIG. 2, the growth chamber 152 includes two portions—a lower segment chamber 155 (or simply “lower chamber”) and an upper growth chamber 165 (or simply “upper chamber”) disposed above the lower segment chamber 155 that are separated by an isolation valve 170 (or isolation valve housing 172). The hotzone of the ingot puller apparatus 100 (e.g., crucible, reflector, susceptor, heaters, and the like) is disposed within the lower chamber 155. During ingot growth, the ingot 113 is pulled through the lower chamber 155 and continues to be pulled through the upper chamber 165 as the ingot is lengthened.

The ingot puller housing 108 includes a lower segment 119 that defines the lower chamber 155 and an upper segment 140 that defines the upper chamber 165. At least a portion of the lower segment 119 has a diameter greater than the upper segment 140. The lower segment 119 includes a dome-shaped portion 169 which tapers in size to the diameter of the upper segment 140. The upper segment 140 is generally cylindrical in shape.

The crucible assembly 102 (FIG. 1) is disposed in the lower chamber 155. The crucible assembly 102 has a sidewall 131 and floor 129 and rests on a susceptor 106. The susceptor 106 is supported by a shaft 105. The susceptor 106, crucible assembly 102, shaft 105, and ingot 113 have a common longitudinal axis or “pull axis” A₁₀₀.

The ingot puller apparatus 100 includes a pulling mechanism 114 for growing and pulling an ingot 113 from the melt 104. The pulling mechanism 114 includes a pull cable 118, a seed holder or chuck 120 coupled to one end of the pull cable 118, and a seed crystal 122 coupled to the chuck 120 for initiating crystal growth. One end of the pull cable 118 is connected to a pulley (not shown) or a drum (not shown) of the pulling mechanism 114 and the other end is connected to the chuck 120 that holds the seed crystal 122. The pulling mechanism 114 includes a motor that rotates the pulley or drum.

In operation, the seed crystal 122 is lowered to contact the surface 111 of the melt 104. The pulling mechanism 114 is operated to cause the seed crystal 122 to rise. This causes a single crystal ingot 113 to be pulled from the melt 104.

During heating and crystal pulling, a crucible drive unit 107 (e.g., a motor) rotates the crucible assembly 102 and susceptor 106. A lift mechanism 112 raises and lowers the crucible assembly 102 along the pull axis A₁₀₀ during the growth process. For example, the crucible assembly 102 may be at a lowest position (near the bottom heater 126) in which a charge of solid-phase silicon 133 previously added to the crucible assembly 102 is melted. Crystal growth commences by contacting the melt 104 with the seed crystal 122 and lifting the seed crystal 122 by the pulling mechanism 114.

A crystal drive unit (not shown) may also rotate the pulling cable 118 and ingot 113 in a direction opposite the direction in which the crucible drive unit 107 rotates the crucible assembly 102 (e.g., counter-rotation). In embodiments using iso-rotation, the crystal drive unit may rotate the pulling cable 118 in the same direction in which crucible drive unit rotates the crucible assembly 102.

The ingot puller apparatus 100 includes bottom insulation 110 and side insulation 124 to retain heat in the puller apparatus 100. In the illustrated embodiment, the ingot puller apparatus 100 includes a bottom heater 126 disposed below the crucible floor 129. The crucible assembly 102 may be moved to be in relatively close proximity to the bottom heater 126 to melt the solid silicon charged to the crucible assembly 102.

According to the Czochralski single crystal growth process, a quantity of solid-phase silicon such as polycrystalline silicon, or “polysilicon”, is initially charged to the crucible assembly 102. The semiconductor or solar-grade solid silicon that is introduced into the crucible assembly 102 is melted by heat provided from one or more heating elements. Once the melt 104 is fully formed, the seed crystal 122 is lowered and contacted with the surface 111 of the melt 104. The pulling mechanism 114 is operated to pull the seed crystal 122 from the melt 104. The resulting ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104.

The crystal growth process may be a batch process in which solid-state silicon is initially added to the crucible assembly 102 to form a silicon melt without additional solid-state silicon being added to the crucible assembly 102 during crystal growth. In other embodiments, the crystal growth process is a continuous Czochralski process in which an amount of silicon is added the crucible assembly during ingot growth.

The ingot puller apparatus 100 includes a side heater 135 and a susceptor 106 that encircles the crucible assembly 102 to maintain the temperature of the melt 104 during crystal growth. The side heater 135 is disposed radially outward to the crucible sidewall 131 as the crucible assembly 102 travels up and down the pull axis A₁₀₀. The side heater 135 and bottom heater 126 may be any type of heater that allows the side heater 135 and bottom heater 126 to operate as described herein. In some embodiments, the heaters 135, 126 are resistance heaters. The side heater 135 and bottom heater 126 may be controlled by a control system (not shown) so that the temperature of the melt 104 is controlled throughout the pulling process.

The ingot puller apparatus 100 may include a heat shield 151. The heat shield 151 may shroud the ingot 113 and may be disposed within the crucible assembly 102 during crystal growth. The ingot puller apparatus 100 may include an inert gas system to introduce and withdraw an inert gas such as argon from the growth chamber 152.

The ingot 102 is shrouded by a cooling jacket 132. The heat shield 151 and the cooling jacket 132 are each mounted within the lower chamber 155 above the melt 104. The heat shield 151 is mounted radially outward from the cooling jacket 132, and defines an elongate passage 134 sized and shaped to receive the ingot 113 as the ingot 113 is pulled up from the melt 104 along the pull axis A₁₀₀. The heat shield 151 is mounted above the melt-gas interface 126 such that a gap 136 is defined therebetween. The cooling jacket 132 is positioned radially inward from the heat shield 151, and within the elongate passage 134. The cooling jacket 132 is concentrically arranged with the heat shield 151 along the pull axis A₁₀₀, and defines a central passage 144 for receiving the ingot 113 as the ingot 113 is pulled along the pull axis A₁₀₀ by the pulling mechanism 114. The heat shield 151 insulates and/or reflects radiant heat away from the ingot 113 as the ingot is pulled through the passage 134. The cooling jacket 132 may be in the form of a cylindrical, fluid-cooled heat exchanger that facilitates cooling of the ingot 113 as the ingot 113 is pulled through the passage 144. The heat shield 151 and the cooling jacket 132 may facilitate controlling axial and radial temperature gradients, which drive solidification and crystallization of molten silicon in the melt 104 into the growing ingot 113. The configuration of the heat shield 151 and the cooling jacket 132 may vary to enhance temperature effects within the passages 134, 140 as the ingot 113 is pulled therethrough.

The illustrated ingot puller apparatus 100 is an example ingot puller apparatus and other ingot puller apparatus that are suitable for growing a single crystal silicon ingot may be used unless stated otherwise.

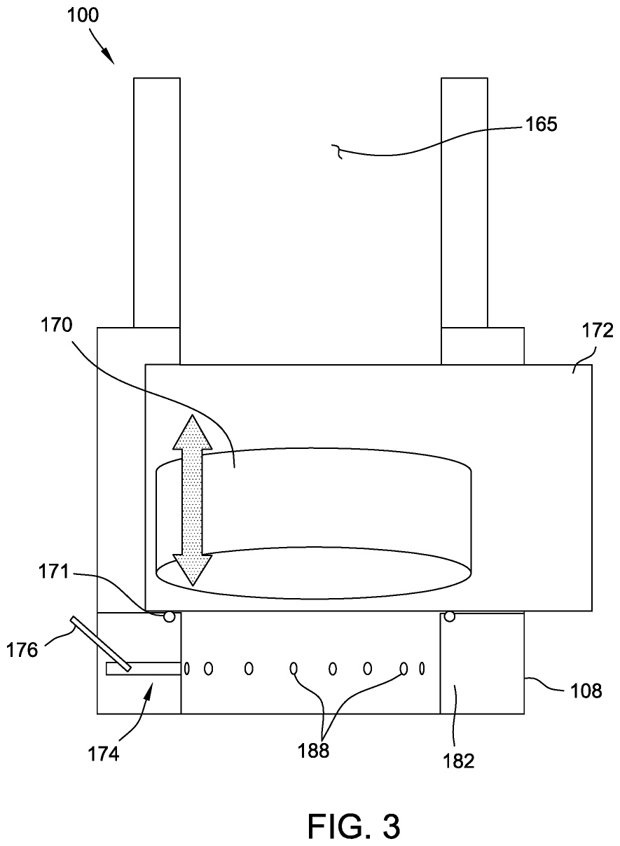

Referring now to FIG. 3, the ingot puller apparatus 100 includes an isolation valve 170. The isolation valve 170 is moveable between an open position in which the lower segment chamber 155 (FIG. 2) is in fluid communication with the upper segment chamber 165 and a closed position in which the lower segment chamber 155 is sealed from the upper segment chamber 165. In the illustrated embodiment, the isolation valve 170 is a plate that is seated against an o-ring 171. The isolation valve 170 may be a “flipping type” or “swinging type” valve. The isolation valve 170 may be disposed within an isolation valve housing 172. In some embodiments, the isolation valve 170 is in the smaller diameter cylindrical portion of the ingot puller apparatus.

The ingot puller apparatus 100 includes a process gas feed assembly 174 for adding a process gas (e.g., inert gas such as argon) to the lower segment chamber 155. The process gas feed assembly 174 includes a first inlet 176 that extends through the ingot puller housing 108 for introducing the process gas into the growth chamber 152. The process gas flows from a source of process gas 200 (FIG. 2) through the inlet 176 and downward towards a process gas outlet 177 (FIG. 1) disposed below the crucible assembly 102. The first inlet 176 is below the isolation valve 170 (i.e., at a height less than the isolation valve 170 relative to the pull axis A₁₀₀ (FIG. 1)) such that the process gas can circulate through the lower chamber 155 even when valve 170 is closed.

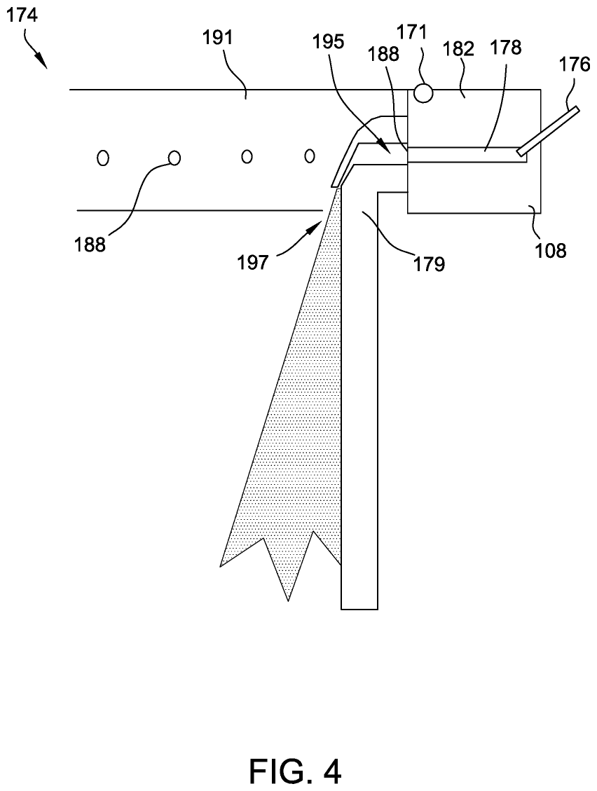

Referring now to FIG. 4, the process gas feed assembly 174 includes an annular process gas manifold 182. The manifold 182 includes a process gas plenum 178 within the manifold 182. The plenum 178 is in fluid communication with the first inlet 176. The annular process gas manifold 182 includes one or more outlets 188 that extend through an inner surface 191 of the manifold 182. The outlets 188 are in fluid communication with the process gas plenum 178. The manifold 182 is disposed below the isolation valve 170 relative to the pull axis A₁₀₀ (FIG. 1) of the ingot puller apparatus 100.

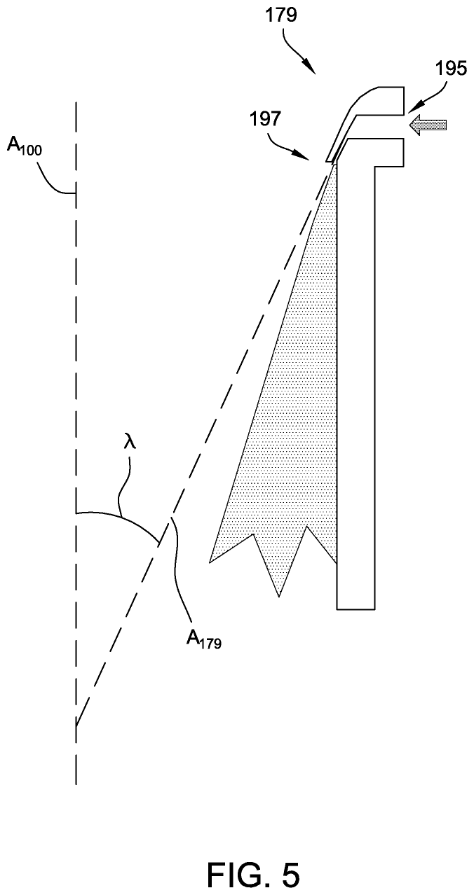

In the embodiment illustrated in FIG. 4, the process gas feed assembly 174 includes a nozzle 179. The nozzle 179 is in fluid communication with the inlet 176 for directing process gas into the lower chamber 155 (FIG. 2). The nozzle 179 may be aligned with an outlet 188 of the manifold 182 and is in fluid communication with the process gas plenum 178 and the inlet 176. Each nozzle 179 has a nozzle inlet 195 (FIG. 5) (aligned with the outlet 188) and a nozzle outlet 197. The size (i.e., cross-sectional area) of the nozzle inlet 195 is greater than the size of the nozzle outlet 197 to cause the process gas to increase velocity as it is discharged from the nozzle 179. The nozzle 179 changes the direction of flow of the process gas.

Each nozzle 179 has a discharge axis A₁₇₉. The discharge axis A₁₇₉ forms an angle λ with the pull axis A₁₀₀ of the ingot puller apparatus 100. In some embodiments, the angle λ is 45° or less or, as in other embodiments, 30° or less, 25° or less, or 10° or less. In yet other embodiments, the discharge axis A₁₇₉ is parallel to pull axis A₁₀₀ of the ingot puller apparatus.

The process gas feed assembly 174 may include one nozzle, or at least two, at least four, or at least ten nozzles that are in fluid communication with the inlet 176 for directing process gas into the lower segment chamber 155 (FIG. 2). If multiple nozzles 179 are used, the nozzles 179 may be spaced (e.g., evenly spaced) about the manifold 182.

The ingot puller apparatus 100 also includes a second process gas inlet 199 (FIG. 2) which may be used to introduce process gas into the upper segment chamber 165 (e.g., when the isolation valve 170 is open). The second inlet 199 extends into the ingot puller housing 108 and is in fluid communication with a source of process gas 200 (e.g., argon).

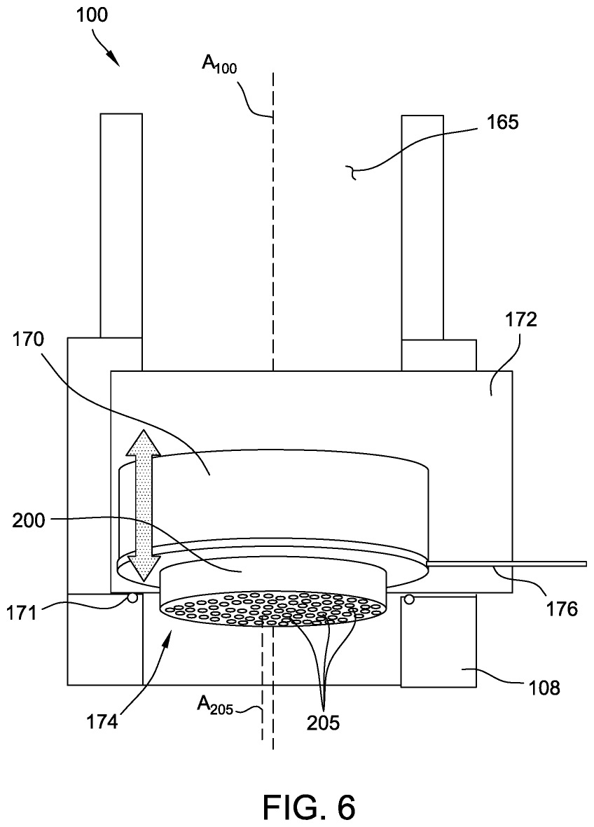

Another embodiment of a process gas feed assembly 174 is shown in FIG. 6. The illustrated process gas feed assembly 174 may be used in the example ingot puller apparatus 100 shown in FIGS. 1-2. The process gas feed assembly 174 includes an inlet 176 that extends through the ingot puller housing 108 for introducing a process gas into the growth chamber 152. The process gas feed assembly 174 also includes a shower plate 200 that is disposed below the isolation valve 170 and that is in fluid communication with the inlet 176. The shower plate 200 includes a plurality of outlets 205 for discharging process gas into the lower segment chamber 155 (FIG. 2). For example, the shower plate 200 may include at least 5 openings 205, at least 10 openings 205, at least 20 openings 205, or at least 25 openings 205. The isolation valve 170 may include a gas plenum within the isolation valve 170 with the plenum being in fluid communication with the 176 inlet of the process gas feed assembly 174 and with the plurality of outlets 205 of the shower plate 200.

Each outlet 205 of the shower plate has a longitudinal axis A₂₀₅. In the embodiment illustrated in FIG. 6, the longitudinal axis A₂₀₅ is parallel to the pull axis A₁₀₀ of the ingot puller apparatus. In other embodiments, the longitudinal axis A₂₀₅ of each outlet 205 forms an angle with the pull axis. The angle may be 45° or less, 30° or less, 25° or less or 10° or less.

In some embodiments and as shown in FIG. 6, the shower plate 200 is connected (e.g., cast with, welded, or fastened) to the isolation valve 170. The shower plate 200 moves with the isolation valve 170 between the open position and the closed position.

In some embodiments, the flow of process gas is controlled during ingot growth (i.e., during ingot cooling) to reduce deposit formation in the lower chamber 155. After ingot growth (i.e., formation of an end cone), the single crystal silicon ingot 113 (FIG. 1) is separated from the melt 104. The ingot 113 (e.g., the entire ingot) is pulled into the upper chamber 165 and above the isolation valve 170 by the pulling mechanism 114. The pulling mechanism 114 is stopped and the single crystal silicon ingot cools. During cooling, the isolation valve 170 is in the open position and process gas flows through the second inlet 199 (FIG. 2), through the upper chamber 165, through the isolation valve housing 172 and into the lower chamber 155 (without flow through the first inlet 176). The cooled ingot 113 may be withdrawn from the upper segment 140 (through a cover that is opened for removal of the ingot) with the isolation valve 170 being in the closed position (and with process gas passing through the first inlet 176 and not the second inlet 199).

The ingot puller apparatus 100 may include a first process gas valve 209 (FIG. 2) for regulating the flow of process gas from the source of process gas 200 and the first inlet 176. The first process gas valve 209 is moveable between an open position in which the first inlet 176 is in fluid communication with the source of process gas 200 and a closed position in which process gas cannot flow from the source of process gas 200 through the first inlet 176. The apparatus 100 may also include a second process gas valve 211 for regulating the flow of process gas from the source of process gas 200 and the second inlet 199. The second process gas valve 211 is moveable between an open position in which the second inlet 199 is in fluid communication with the source of process gas 200 and a closed position in which process gas cannot flow from the source of process gas 200 through the second inlet 199. While cooling the ingot in the upper chamber 165 (with isolation valve 170 open), the first process gas valve 209 is in the closed position and the second process gas valve 211 is in the open position. When withdrawing the single crystal silicon ingot 113 from the upper segment chamber 165 (with the isolation valve being closed), the first process gas valve 209 is in the open position and the second process gas valve 211 is in the closed position which allows process gas to be introduced below the closed isolation valve 170 and to flow into the lower chamber 155.

Methods for reducing the time at which the isolation valve is closed (i.e., by cooling the ingot with the valve open) may be combined with any of the ingot puller constructions (i.e., process gas feed assemblies 174) described above.

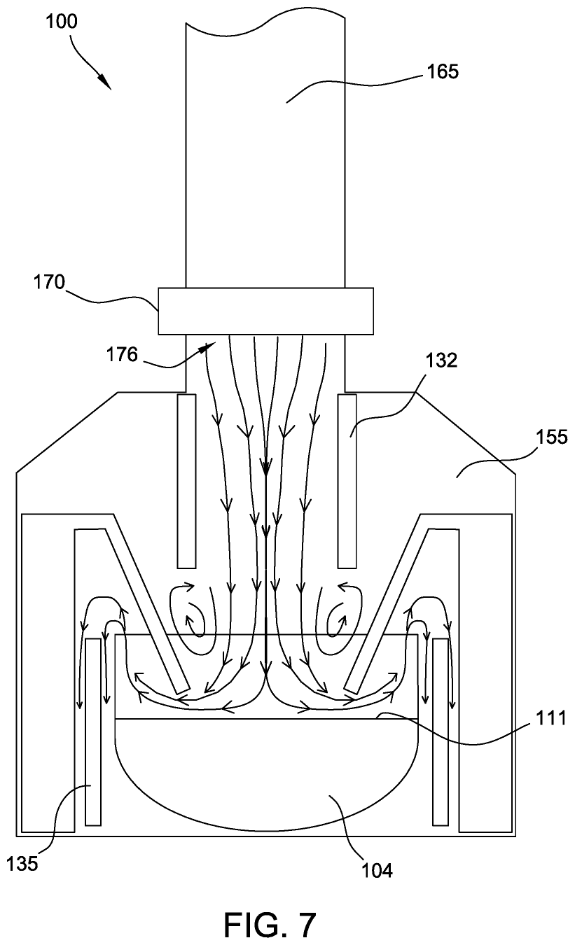

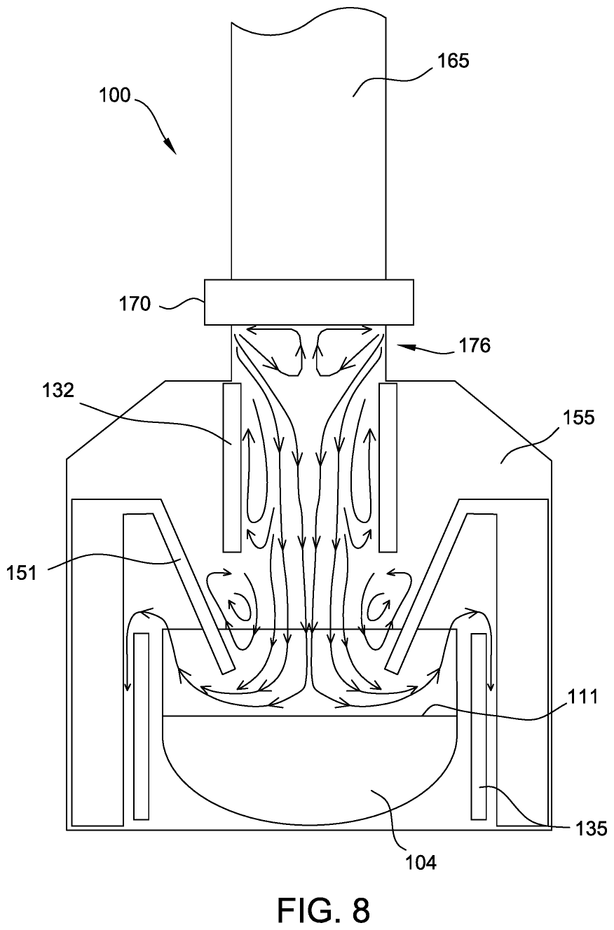

Compared to conventional ingot puller apparatus and methods for forming a single crystal silicon ingot, the apparatus and methods of the present disclosure have several advantages. In embodiments in which the ingot puller apparatus includes a nozzle which directs process gas from the first inlet downward, the process gas may flow through the lower segment chamber in a more vertical and/or laminar manner when the isolation valve is closed (FIG. 8). In embodiments in which the ingot puller apparatus includes a shower plate positioned below the isolation valve, the process gas may flow through the lower segment chamber in a more vertical and/or laminar manner when the isolation valve is closed (FIG. 7). A more vertical and/or laminar of flow of process gas reduces backflow of process gas and reduces deposition of oxides and other particles in the lower chamber which reduces the frequency at which particles fall into the melt and cause loss of zero dislocation. Turbulence in the lower chamber and a gas vortex above the melt free surface may be reduced by use of a more vertical flow of process gas which reduces evaporation of gas from the melt toward the upper hotzone (e.g., reflector and cooling jacket) and the walls of the upper portion of the lower segment chamber. In embodiments in which the isolation valve is open during cooling, gas may flow from the process gas inlet that is above the isolation valve for longer periods which reduces deposits and loss of Zero Dislocation.

### EXAMPLES

The processes of the present disclosure are further illustrated by the following Examples. These Examples should not be viewed in a limiting sense.

### Example 1: Effect of an Open Isolation Valve during Ingot Cooling on Loss of Zero Dislocation

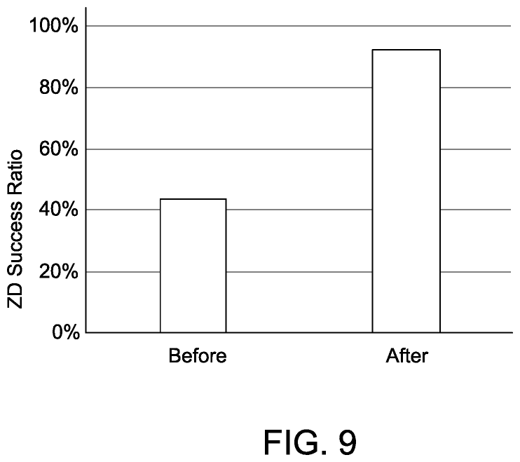

In an ingot puller apparatus similar to the example apparatus shown in FIGS. 1-2, after ingot formation, the single crystal silicon ingot was pulled fully into the upper segment chamber 165. The isolation valve 170 was left open during cooling of the ingot in the upper segment chamber. The second valve 211 was left open and the first valve 209 was closed such that process gas flowed vertically through the upper chamber 165 and into the lower chamber 155. By positioning the valve 170 to be open during cooling, the valve 170 was open an additional 1-4 hours compared to the process of record. This was repeated for a number of ingots (multiple pullers over a series of months) to determine the effect on Zero Dislocation (ZD) success. As shown in FIG. 9, reducing the time that the isolation valve was closed (“After”) increased ZD success. Opening the isolation valve during cooling reduced oxide and volatile gas deposition on the upper portions of the lower segment chamber 152 and cooling jacket which resulted in a cleaner ingot puller apparatus and reduced particles falling into the melt and causing loss of zero dislocation.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. An ingot puller apparatus for producing a single crystal silicon ingot comprising:
a crucible assembly for holding a silicon melt;
an ingot puller housing that defines a growth chamber for pulling a single crystal silicon ingot from the silicon melt, the crucible assembly being disposed within the growth chamber, the ingot puller housing comprising:
a lower segment that defines a lower segment chamber, the crucible assembly being disposed in the lower segment chamber; and
an upper segment disposed above the lower segment that defines an upper segment chamber; and
an isolation valve that is moveable between an open position in which the lower segment chamber is in fluid communication with the upper segment chamber and a closed position in which the lower segment chamber is sealed from the upper segment chamber;
a process gas feed assembly comprising:
an inlet that extends through the ingot puller housing for introducing a process gas into the growth chamber; and
a nozzle in fluid communication with the inlet for directing process gas into the lower segment chamber.

2. The ingot puller apparatus as set forth in claim 1 wherein the nozzle has a discharge axis, the discharge axis forming an angle with a pull axis of the ingot puller apparatus, the angle being 45° or less.

3. The ingot puller apparatus as set forth in claim 2 wherein the nozzle has a discharge axis, the discharge axis being parallel to pull axis of the ingot puller apparatus.

4. The ingot puller apparatus as set forth in claim 1 further comprising an annular process gas manifold, the manifold being disposed below the isolation valve relative to a pull axis of the ingot puller apparatus, the manifold comprising a process gas plenum therein, the process gas plenum being in fluid communication with nozzle.

5. The ingot puller apparatus as set forth in claim 4 wherein the annular process gas manifold comprises one or more outlets that extend through an inner surface of the manifold and that are in fluid communication with the process gas plenum, the nozzle being aligned with an outlet of the process gas manifold.

6. The ingot puller apparatus a set forth in claim 1 comprising at least two, at least four, or at least 10 nozzles in fluid communication with the inlet for directing process gas into the lower segment chamber.

7. The ingot puller apparatus as set forth in claim 1 wherein the nozzle comprises a nozzle inlet and a nozzle outlet, the nozzle inlet having a cross-sectional area greater than a cross-sectional area of the nozzle outlet.

8. The ingot puller apparatus as set forth in claim 1 wherein the inlet is a first inlet, the ingot puller apparatus comprising a second inlet that extends through the ingot puller housing for introducing a process gas into the upper segment chamber.

9. The ingot puller apparatus as set forth in claim 1 wherein the lower segment includes a dome-shaped section and the upper segment is cylindrical, the upper segment having a diameter less than a diameter of the lower segment.

10. An ingot puller apparatus for producing a single crystal silicon ingot comprising:
a crucible assembly for holding a silicon melt;
an ingot puller housing that defines a growth chamber for pulling a single crystal silicon ingot from the silicon melt along a pull axis, the crucible assembly being disposed within the growth chamber, the ingot puller housing comprising:
a lower segment that defines a lower segment chamber, the crucible assembly being disposed in the lower segment chamber; and
an upper segment disposed above the lower segment that defines an upper segment chamber; and
an isolation valve that is moveable between an open position in which the lower segment chamber is in fluid communication with the upper segment chamber and a closed position in which the lower segment chamber is sealed from the upper segment chamber;
a process gas feed assembly comprising:
an inlet that extends through the ingot puller housing for introducing a process gas into the growth chamber; and
a shower plate disposed below the isolation valve, the shower plate being in fluid communication with the inlet, the shower plate comprising a plurality of outlets for discharging process gas into the lower segment chamber.

11. The ingot puller apparatus as set forth in claim 10 wherein each outlet has a longitudinal axis, the longitudinal axis (1) being parallel to the pull axis or (2) forming an angle with the pull axis of 45° or less.

12. The ingot puller apparatus as set forth in claim 11 wherein the longitudinal axis is parallel to the pull axis.

13. The ingot puller apparatus as set forth in claim 11 wherein the longitudinal axis of each outlet forms an angle with the pull axis of 10° or less.

14. The ingot puller apparatus as set forth in claim 10 wherein the shower plate is connected to the isolation valve and moves with the isolation valve between the open position and the closed position.

15. The ingot puller apparatus as set forth in claim 10 wherein the isolation valve defines a process gas plenum therein, the process gas plenum being in fluid communication with the inlet of the process gas feed assembly and with the plurality of outlets of the shower plate.

16. The ingot puller apparatus as set forth in claim 10 wherein the shower plate comprises at least 5 openings.

17. The ingot puller apparatus as set forth in claim 10 wherein the inlet is a first inlet, the ingot puller apparatus comprising a second inlet that extends through the ingot puller housing for introducing a process gas into the upper segment chamber.

18. The ingot puller apparatus as set forth in claim 10 wherein the lower segment in includes a dome-shaped section and the upper segment is cylindrical, the upper segment having a diameter less than a diameter of the lower segment.

19. A method for forming a single crystal silicon ingot in an ingot puller apparatus, the ingot puller apparatus comprising a crucible assembly for holding a silicon melt, an ingot puller housing that defines a growth chamber for pulling a single crystal silicon ingot from the silicon melt, the crucible assembly being disposed within the growth chamber, the ingot puller housing comprising a lower segment that defines a lower segment chamber, the crucible assembly being disposed in the lower segment chamber, and an upper segment disposed above the lower segment that defines an upper segment chamber, and an isolation valve that is moveable between an open position in which the lower segment chamber is in fluid communication with the upper segment chamber and a closed position in which the lower segment chamber is sealed from the upper segment chamber, the method comprising:
adding a charge of solid-state silicon to the crucible assembly;
heating the crucible assembly comprising the charge of silicon to cause a silicon melt to form in the crucible assembly;
contacting a silicon seed crystal with the silicon melt;
withdrawing the silicon seed crystal along a pull axis to grow a single crystal silicon ingot;
separating the single crystal silicon ingot from the melt;
cooling the single crystal silicon ingot while the ingot is fully within the upper segment chamber after separating the single crystal silicon ingot from the melt, the isolation valve being in the open position while cooling the single crystal silicon ingot;
directing process gas through the upper segment chamber and into the lower segment chamber while cooling the single crystal silicon ingot in the upper segment chamber; and
withdrawing the single crystal silicon ingot from the upper segment chamber, the isolation valve being in the closed position while withdrawing the single crystal silicon ingot.

20. The method as set forth in claim 19 wherein the ingot puller apparatus comprises:
a first inlet for introducing process gas directly into the lower segment chamber;
a first process gas valve moveable between an open position in which the first inlet is in fluid communication with a source of process gas and a closed position in which process gas cannot flow from the source of process gas through the first inlet;
a second inlet for introducing process gas directly into the upper segment chamber; and
a second process gas valve moveable between an open position in which the second inlet is in fluid communication with the source of process gas and a closed position in which process gas cannot flow from the source of process gas through the second inlet, wherein the first process gas valve is in the closed position and the second process gas valve is in the open position while cooling the single crystal silicon while cooling the single crystal silicon ingot in the upper segment chamber, the first process gas valve being in the open position and the second process gas valve being in the closed position while withdrawing the single crystal silicon ingot from the upper segment chamber.
